(19) United States
(12) Patent Application Publication
(10) Pub. No.: US 2025/0386628 A1
(43) Pub. Date: Dec. 18, 2025

(54) DISPLAY DEVICE, ELECTRONIC DEVICE AND METHOD OF MANUFACTURING DISPLAY DEVICE

(71) Applicant: Samsung Display Co., LTD., Yongin-si (KR)

(72) Inventors: Won Ho LEE, Yongin-si (KR); Yang Gyu JANG, Yongin-si (KR); Dal Rae JIN, Yongin-si (KR)

(21) Appl. No.: 19/197,189

(22) Filed: May 2, 2025

(30) Foreign Application Priority Data
Jun. 17, 2024 (KR) 10-2024-0078262
Aug. 27, 2024 (KR) 10-2024-0115141

(51) Int. Cl. H10H 29/01; H10H 29/49; H10H 29/80

(52) U.S. Cl. CPC H10H 29/011; H10H 29/012; H10H 29/032; H10H 29/49; H10H 29/8321

(57) ABSTRACT

A method of manufacturing a display device includes forming a semiconductor stacked structure on a growth substrate; forming a base bonding electrode on the semiconductor stacked structure; forming a semiconductor stacked pattern and a first bonding electrode by respectively etching the semiconductor stacked structure and the base bonding electrode; and bonding the first bonding electrode on a pixel circuit layer.

This application claims priority to Korean Patent Application No. 10-2024-0078262, filed on Jun. 17, 2024, and Korean Patent Application No. 10-2024-0115141, filed on Aug. 27, 2024, and all the benefits accruing therefrom under 35 U.S.C. § 119, the contents of which in their entirety are herein incorporated by reference.

### BACKGROUND

### 1. Field

The present disclosure relates to a display device, an electronic device, and a method of manufacturing the display device.

### 2. Description of the Related Art

With the development of information technology, the importance of a display device, which is a connection medium between users and information, has been highlighted. Accordingly, research and development for display devices is continuously being conducted.

### SUMMARY

The present disclosure provides a display device and a method of manufacturing the display device, which can reduce the risk of components of the display device being damaged during a manufacturing process of the display device.

A method of manufacturing a display device according to an embodiment of the present disclosure includes forming a semiconductor stacked structure on a growth substrate; forming a base bonding electrode on the semiconductor stacked structure; forming a semiconductor stacked pattern and a first bonding electrode by respectively etching the semiconductor stacked structure and the base bonding electrode; and bonding the first bonding electrode on a pixel circuit layer.

According to an embodiment, the forming the semiconductor stacked pattern and the first bonding electrode may include trimming a side surface of each of the semiconductor stacked structure and the base bonding electrode.

According to an embodiment, the trimming may be performed between the forming a base bonding electrode on the semiconductor stacked structure and the bonding the first bonding electrode on the pixel circuit layer.

According to an embodiment, the trimming step may include etching the semiconductor stacked structure with at least one of a knife or a laser while rotating the growth substrate.

According to an embodiment, the forming the semiconductor stacked pattern and the first bonding electrode may include etching the semiconductor stacked structure and the base bonding electrode such that an end of the semiconductor stacked pattern and an end of the first bonding electrode are coincided.

According to an embodiment, the forming the semiconductor stacked pattern and the first bonding electrode may include etching the semiconductor stacked structure and the base bonding electrode such that a side surface of the semiconductor stacked pattern and a side surface of the first bonding electrode form a same plane.

According to an embodiment, the semiconductor stacked pattern and the first bonding electrode may be formed within a same etching process.

According to an embodiment, the semiconductor stack structure may be etched to a thickness of 2 mm or less, and the thickness may be defined in a direction in which a plane on which the growth substrate is disposed extends.

According to an embodiment, the forming the semiconductor stacked pattern and the first bonding electrode may include etching the growth substrate such that a step is formed in an upper surface of the growth substrate.

According to an embodiment, the method may further include polishing a surface of the first bonding electrode.

According to an embodiment, the method may further include forming a second bonding electrode on the pixel circuit layer, wherein, in the bonding the first bonding electrode, the first bonding electrode may be bonded to the second bonding electrode.

According to an embodiment, an end of the base bonding electrode formed in the forming the base bonding electrode does not coincide with an end of the semiconductor stacked structure.

According to an embodiment, in the forming the base bonding electrode, the base bonding electrode may be not deposited on an area of the semiconductor stacked structure, and the area may overlap an edge of the semiconductor stacked structure in a plan view.

According to an embodiment, the method may further include removing the growth substrate, wherein the removing the growth substrate may include grinding a portion of the growth substrate, and etching a remaining portion of the growth substrate.

According to an embodiment, the grinding a portion of the growth substrate may include grinding the growth substrate until a growth substrate thickness of the growth substrate is 30 μm to 70 μm.

According to an embodiment, the growth substrate may include silicon, and the semiconductor stack structure may include a first base semiconductor part epitaxially grown on the growth substrate, a base active layer part epitaxially grown on the first base semiconductor part; and a second base semiconductor part epitaxially grown on the base active layer part.

A display device according to an embodiment of the present disclosure includes: a pixel circuit layer; a first bonding electrode disposed on the pixel circuit layer; and a light emitting element disposed on the first bonding electrode, wherein the light emitting element includes: a first semiconductor layer; a second semiconductor layer; and an active layer interposed between the first semiconductor layer and the second semiconductor layer, and wherein each of the first semiconductor layer, the second semiconductor layer, and the active layer may have an end coinciding with an end of the first bonding electrode.

According to an embodiment, a side surface of the first semiconductor layer, a side surface of the second semiconductor layer, and a side surface of the active layer may form a same plane as a side surface of the first bonding electrode.

According to an embodiment, the display device may further include a second bonding electrode disposed on the pixel circuit layer, wherein the second bonding electrode may be bonded to the first bonding electrode, and a portion of an end of the second bonding electrode may coincide with the end of the first bonding electrode.

According to an embodiment, a remaining portion of the end of the second bonding electrode, excluding the portion of the end of the second bonding electrode, may protrude outwardly from the end of the first bonding electrode.

According to an embodiment of the present disclosure, a display device and a method of manufacturing the display device may be provided, which can reduce the risk of components of the display device being damaged during a manufacturing process of the display device.

### BRIEF DESCRIPTION OF THE DRAWINGS

FIG. 1 is a schematic plan view illustrating a display device according to an embodiment.

FIG. 2 is a schematic cross-sectional view illustrating a display device according to an embodiment.

FIG. 3 is a schematic block diagram illustrating an electrical connection structure for a light emitting element according to an embodiment.

FIG. 4 is a schematic cross-sectional view of a display device according to an embodiment.

FIG. 5 is a schematic flowchart illustrating a method of manufacturing a display device according to an embodiment.

FIGS. 6 to 12 are schematic cross-sectional views illustrating process steps of a method of manufacturing a display device.

FIG. 13 is a block diagram of an electronic device according to an embodiment.

FIG. 14 shows schematic views of various embodiments of an electronic device.

### DETAILED DESCRIPTION

It will be apparent to those skilled in the art that various modifications and variations can be made in the present disclosure without departing from the spirit or scope of the disclosure, and specific example embodiments are described in the drawings and explained in the detailed description. Thus, it is intended that the present invention covers the modifications and variations of this invention provided they come within the scope of the present invention and their equivalents.

The terms, ‘first’, ‘second’ and the like may be simply used for description of various constituent elements, but those meanings may not be limited to the restricted meanings. the terms are used for distinguishing one constituent element from other constituent elements. For example, a first constituent element may be referred to as a second constituent element and similarly, the second constituent element may be referred to as the first constituent element within the scope of the appended claims. In an example in which explaining the singular, unless explicitly described to the contrary, it may be interpreted as the plural meaning.

In the specification, the word “comprise” or “has” is used to specify existence of a feature, a numbers, a process, an operation, a constituent element, a part, or a combination thereof, and it will be understood that existence or additional possibility of one or more other features or numbers, processes, operations, constituent elements, parts, or combinations thereof are not excluded in advance. In some aspects, it will be understood that when an element such as, for example, a layer, film, area, or substrate is referred to as being “on” another element, the element can be directly on the other element or intervening elements may also be present. In the specification, it will be understood that when an element such as, for example, a layer, film, area, or substrate is referred to as being disposed “on” another element, the disposed direction is not limited to an upper direction and include a side portion direction or a lower direction. In contrast, it will be understood that when an element such as, for example, a layer, film, area, or substrate is referred to as being “beneath” another element, the element can be directly beneath the other element or intervening elements may also be present.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The present disclosure relates to a display device and a method of manufacturing the display device. Hereinafter, a display device and a method of manufacturing the display device according to embodiments will be described with reference to the accompanying drawings.

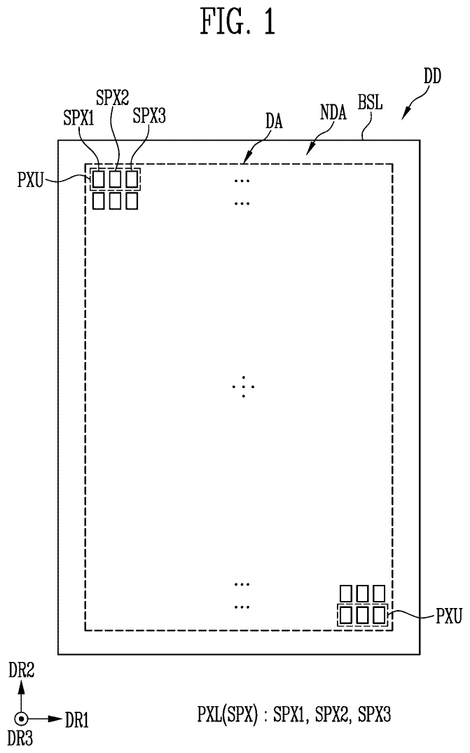

FIG. 1 is a schematic plan view illustrating a display device according to an embodiment.

Referring to FIG. 1, the display device DD may include a base layer BSL and a pixel PXL disposed on the base layer BSL. Although not illustrated in the drawing, the display device DD may further include a driving circuit unit (e.g., a scan driver and a data driver) for driving the pixel PXL, lines, and pads.

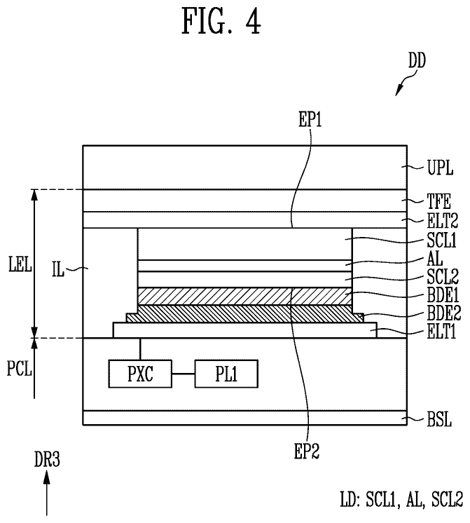

The display device DD is configured to emit light. The display device DD includes a light emitting element LD (see FIG. 4). According to the embodiment, the display device DD may be a device that displays moving images or still images. The display device DD can be used as a display screen of not only portable electronic devices such as, for example, a mobile phone, a smart phone, a tablet personal computer (tablet PC), a smart watch, a watch phone, a mobile communication terminal, an electronic notebook, an electronic book, a portable multimedia player (PMP), a navigation, an ultra-mobile PC (UMPCs), and the like, but also various products such as, for example, a television, a laptop, a monitor, a billboard, an internet of things (IOT), and the like. However, an application field of the display device DD is not limited to a specific example.

The display device DD may be formed in a rectangular plane having a short side in the first direction DR1 and a long side in the second direction DR2 crossing the first direction DR1. An edge where the short side of the first direction DR1 and the long side of the second direction DR2 meet may be formed such that the edge is rounded and has a predetermined curvature or may be formed such that the edge has a right angle. The planar shape of the display device DD may be not limited to a quadrangle, and may be formed in other polygons or a round shape such as, for example, a circle or an ellipse. The display device DD may be formed such that the display device DD is flat, but is not limited thereto. For example, the display device DD may include curved portions formed at left and right ends and having a constant curvature or a changing curvature. In some aspects, the display device DD may be flexibly formed such that the display device DD may be curved, warped, bent, folded, or rolled. For example, according to an embodiment, the display device DD may be a flexible display device.

In the present disclosure, the first direction DR1 may be a row direction of the pixel PXL and may be a “horizontal” direction. The second direction DR2 may be a column direction of the pixel PXL. The third direction DR3 may be a display direction of the display device DD or a normal direction of a plane on which the base layer BSL is disposed (or a thickness direction of the base layer BSL).

The display device DD (or base layer BSL) may include a display area DA and a non-display area NDA. The non-display area NDA may refer to an area other than the display area DA. The non-display area NDA may surround at least a portion of the display area DA.

The base layer BSL may form a base surface of the display device DD. The base layer BSL may be a rigid or flexible substrate or film. For example, the base layer BSL may include a glass material. Alternatively, the base layer BSL may include a silicon material. Alternatively, the base layer BSL may include polyimide. However, embodiments of the present disclosure are not limited thereto.

The display area DA may correspond an area in which the pixels PXL are disposed. The non-display area NDA may correspond an area in which the pixel PXL is not disposed. A driving circuit unit, wires, and pads connected to the pixel PXL of the display area DA may be disposed in the non-display area NDA.

According to an embodiment, the pixel PXL (or sub-pixels SPX) may be arranged according to a stripe or PENTILE™ array structure, but embodiments of the present disclosure are not limited thereto, and various embodiments may be provided in the present disclosure.

According to an embodiment, the pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be sub-pixels. At least one of the first sub-pixel SPX1, the second sub-pixel SPX2, and the third sub-pixel SPX3 may form one pixel unit PXU capable of emitting light of various colors.

Each of the first sub-pixel SPX1, the second sub-pixel SPX2, and the third sub-pixel SPX3 may emit light of one color.

For example, the first sub-pixel SPX1 may be a red pixel that emits red light (e.g., first color), the second sub-pixel SPX2 may be a green pixel that emits green light (e.g., second color), and the third sub-pixel SPX3 may be a blue pixel that emits blue light (e.g., third color). The red pixel may provide light in a wavelength range of about 600 nm to about 750 nm. The green pixel may provide light in a wavelength band of about 480 nm to about 560 nm. The blue pixel may provide light in a wavelength band of about 370 nm to about 460 nm.

According to an embodiment, the number of second sub-pixels SPX2 may be greater than the number of first and third sub-pixels SPX1 and SPX3. However, the color, type, and/or number of the first sub-pixel SPX1, the second sub-pixel SPX2, and the third sub-pixel SPX3 forming each pixel unit PXU are not limited to specific examples.

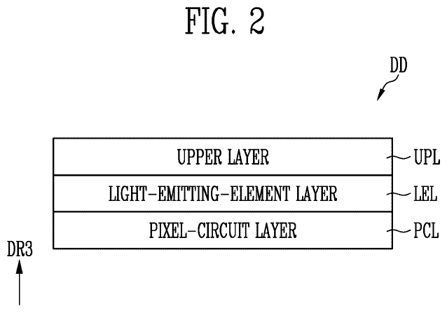

FIG. 2 is a schematic cross-sectional view illustrating a display device according to an embodiment.

Referring to FIG. 2, the display device DD may include a pixel circuit layer PCL, a light emitting element layer LEL, and an upper layer UPL.

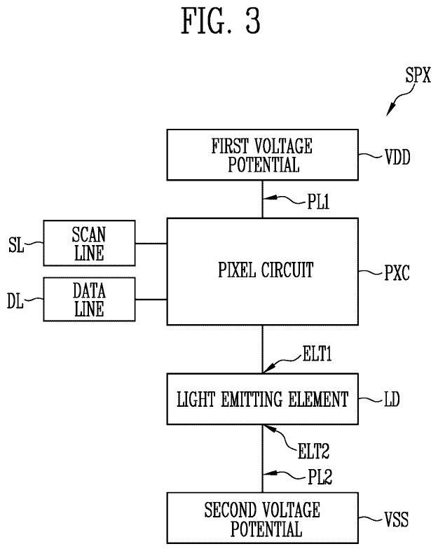

The pixel circuit layer PCL may include a base layer BSL and a pixel circuit PXC (see FIG. 3).

The base layer BSL may form a basis on which the pixel circuit PXC is disposed. The pixel circuit PXC may be disposed on the base layer BSL and may be configured to drive the light emitting element LD. The pixel circuit layer PCL may include conductive layers and insulating layers, and the conductive layers may form the pixel circuit PXC.

The light emitting element layer LEL may be disposed on the pixel circuit layer PCL. The light emitting element layer LEL may include a light emitting element LD. The light emitting element LD may include an inorganic light emitting diode including an inorganic material. For example, the light emitting element LD may include a micro light emitting diode (LED).

The upper layer UPL may be disposed on the light emitting element layer LEL. The upper layer UPL may be transparent to light. According to an embodiment, the upper layer UPL may include a cover window. The upper layer UPL may include color filters and may also include an upper substrate and other elements. However, the present disclosure is not limited to specific examples.

FIG. 3 is a schematic block diagram illustrating an electrical connection structure for a light emitting element according to an embodiment. For example, FIG. 3 may show an electrical connection structure including a pixel circuit PXC corresponding to each sub-pixel SPX.

Referring to FIG. 3, a display device DD (e.g., a sub-pixel SPX) may include a pixel circuit PXC, a scan line SL, a data line DL, a first power line PL1, a second power line PL2, a first electrode ELT1, and a second electrode ELT2, configured to drive the light emitting element LD.

The pixel circuit PXC may include one or more circuit elements. For example, the pixel circuit PXC may include a driving transistor, a switching transistor, a storage capacitor, and other components. However, the present disclosure is not necessarily limited thereto.

The pixel circuit PXC may be electrically connected to a scan line SL and a data line DL. The scan line SL may supply a scan signal to the pixel circuit PXC and, according to an embodiment, may be electrically connected to a gate electrode of a switching transistor of the pixel circuit PXC. The light emitting element LD may be configured to emit light corresponding to a data signal provided from the data line DL.

The pixel circuit PXC may be electrically connected to a first power line PL1 and a second power line PL2. For example, the first electrode ELT1 may be electrically connected to the pixel circuit PXC and the first power line PL1, and the second electrode ELT2 may be electrically connected to the second power line PL2. The first power line PL1 and the second power line PL2 may be disposed on the base layer BSL and, according to an embodiment, may be included in the pixel circuit layer PCL.

The power of the first power line PL1 and the power of the second power line PL2 may have different potentials. For example, the power of the first power line PL1 may be a high-potential pixel power supplied from the first voltage potential VDD, and the power of the second power line PL2 may be a low-potential pixel power supplied from the second voltage potential VSS. The potential difference between the power of the first power line PL1 and the power of the second power line PL2 may be set to be higher than the threshold voltage of the light emitting elements LD.

The first power line PL1 may be electrically connected to the pixel circuit PXC (e.g., a driving transistor). The second power line PL2 may be electrically connected to a cathode electrode of the light emitting element LD (e.g., the second electrode ELT2). According to an embodiment, the second power line PL2 may be electrically connected to the second electrode ELT2.

Each of the light emitting elements LD included in the light emitting unit EMU may be connected in a forward direction between the first power line PL1 and the second power line PL2 to form each effective light source. These effective light sources may be combined to form light emitting elements LD of a sub-pixel SPX.

The light emitting elements LD may emit light with a brightness corresponding to the driving current supplied through the pixel circuit PXC. During each frame period, the pixel circuit PXC may supply the driving current corresponding to the data signal to the light emitting element LD. The light emitting element LD may emit light with a brightness corresponding to the current flowing through it.

FIG. 4 is a schematic cross-sectional view of a display device according to an embodiment.

Referring to FIG. 4, the pixel circuit layer PCL may include a base layer BSL, a pixel circuit PXC disposed on the base layer BSL, and a first power line PL1. Although the second power line PL2 is not illustrated in FIG. 4, in an embodiment, the pixel circuit layer PCL may also include the second power line PL2.

The first power line PL1 may be electrically connected to the pixel circuit PXC and may supply power of the first voltage potential VDD to the pixel circuit PXC. The second power line PL2 may be disposed to be separated from the first power line PL1 and may supply power of the second voltage potential VSS to the second electrode ELT2.

The light emitting element layer LEL may include a first electrode ELT1, a second electrode ELT2, and a light emitting element LD electrically connected between the first and second electrodes ELT1 and ELT2. The light emitting element layer LEL may further include a first bonding electrode BDE1, a second bonding electrode BDE2, an insulating layer IL, and an encapsulating layer TFE.

The first electrode ELT1 and the second electrode ELT2 may include a conductive material and may be electrically connected to other layers within the pixel circuit layer PCL through a contact structure. For example, the first electrode ELT1 may be electrically connected to the pixel circuit PXC, and the second electrode ELT2 may be electrically connected to the second power line PL2. The first electrode ELT1 may be an anode electrode of the light emitting element LD, and the second electrode ELT2 may be a cathode electrode of the light emitting element LD. However, embodiments of the present disclosure are not limited thereto, and according to an embodiment, the first electrode ELT1 may be a cathode electrode of the light emitting element LD, and the second electrode ELT2 may be an anode electrode of the light emitting element LD.

The light emitting element LD may be disposed on the first electrode ELT1. According to an embodiment, the light emitting element LD may include a first semiconductor layer SCL1, a second semiconductor layer SCL2, and an active layer AL. The light emitting element LD may include a first end EP1 adjacent to a first semiconductor layer SCL1 and a second end EP2 adjacent to a second semiconductor layer SCL2. The first end EP1 may be an end adjacent to the second electrode ELT2, and the second end EP2 may be an end adjacent to the first electrode ELT1.

The light emitting element LD may be manufactured based on an epitaxial process and an etching process performed on a separate wafer, and may be transferred onto the pixel circuit layer PCL by various methods.

The light emitting element LD may be aligned vertically on the first electrode ELT1. For example, in a direction from the first end EP1 to the second end EP2, the first semiconductor layer SCL1, the active layer AL, and the second semiconductor layer SCL2 may be sequentially disposed. The direction from the first end EP1 to the second end EP2 may be a direction opposite to the third direction DR3, corresponding to a thickness direction of the base layer BSL.

The light emitting element LD may have various sizes. For example, the light emitting element LD may have a size ranging from nanoscale to microscale. However, embodiments of the present disclosure are not limited thereto.

The first semiconductor layer SCL1 may include a semiconductor of a first conductive type. The first semiconductor layer SCL1 may be disposed on one surface (e.g., the upper surface) of the active layer AL and may include a semiconductor layer of a different type from the second semiconductor layer SCL2. For example, the first semiconductor layer SCL1 may include an N-type semiconductor layer. For example, the first semiconductor layer SCL1 may include one or more semiconductor materials selected from the group consisting of InAlGaN, GaN, AlGaN, InGaN, AlN, and InN, and may include an N-type semiconductor layer doped with a second conductive dopant, such as, for example, Si, Ge, Sn, and the like. However, the present disclosure is not limited to the examples described herein. The first semiconductor layer SCL1 may include various materials.

The first semiconductor layer SCL1 may be adjacent to the second electrode ELT2 and may be disposed to face the second electrode ELT2.

The active layer AL may be disposed between the second semiconductor layer SCL2 and the first semiconductor layer SCL1. The active layer AL may include a single-quantum well or multi-quantum well structure. An position of the active layer AL is not limited to a specific example and may vary depending on a type of the light emitting element LD.

A clad layer doped with a conductive dopant may be formed on one side portion and/or the other side portion of the active layer AL. For example, the clad layer may include one or more of AlGaN and InAlGaN. However, the present disclosure is not limited to the examples described herein.

The second semiconductor layer SCL2 may include a semiconductor of a second conductive type. The second semiconductor layer SCL2 may be disposed on one surface (e.g., the lower surface) of the active layer AL and may include a semiconductor layer of a different type from the first semiconductor layer SCL1. For example, the second semiconductor layer SCL2 may include a P-type semiconductor layer. For example, the second semiconductor layer SCL2 may include one or more semiconductor materials selected from the group consisting of InAlGaN, GaN, AlGaN, InGaN, AlN, and InN, and may include a P-type semiconductor layer doped with a first conductivity type dopant, such as, for example, Ga, B, Mg, and the like. However, the present disclosure is not limited to the examples described herein. The second semiconductor layer SCL2 may include various materials.

The light emitting element LD may be electrically connected to the second electrode ELT2 through the first end EP1. The light emitting element LD may be electrically connected to the first bonding electrode BDE1, the second bonding electrode BDE2, and the first electrode ELT1 through the second end EP2.

When a voltage higher than a threshold voltage is applied to the first end EP1 and the second end EP2 of the light emitting element LD, electron-hole pairs may recombine with each other in the active layer AL, and the light emitting element LD can emit light. By controlling light emitting of the light emitting element LD using this principle, the light emitting element LD can be used as a light source in various devices.

The first bonding electrode BDE1 may be patterned to be disposed on the second semiconductor layer SCL2 when manufacturing the light emitting element LD. The first bonding electrode BDE1 may be a layer for transferring the light emitting elements LD onto the first electrode ELT1 (or the pixel circuit layer PCL). The second bonding electrode BDE2 may be disposed on the pixel circuit layer PCL. For example, the second bonding electrode BDE2 may be disposed on the first electrode ELT1 and bonded to the first bonding electrode BDE1. The second bonding electrode BDE2 may be bonded to each of the first bonding electrode BDE1 and the first electrode ELT1 between the first bonding electrode BDE1 and the first electrode ELT1.

For example, the second bonding electrode BDE2 may be disposed on the first electrode ELT1, and the light emitting elements LD may be disposed on the second bonding electrode BDE2 such that the first bonding electrode BDE1 faces the second bonding electrode BDE2, and heat may be applied to the first bonding electrode BDE1 and the second bonding electrode BDE2, such that the light emitting elements LD and the first electrode ELT1 may be bonded to each other through the first and second bonding electrodes BDE1 and BDE2.

The first bonding electrode BDE1 and the second bonding electrode BDE2 may include various conductive materials. For example, each of the first bonding electrode BDE1 and the second bonding electrode BDE2 may include at least one of titanium (Ti), gold (Au), and tin (Sn).

An end of the first bonding electrode BDE1 may correspond to an end of each of the first semiconductor layer SCL1, the active layer AL, and the second semiconductor layer SCL2. In an example in which viewed on a plane, an end of the first bonding electrode BDE1 may overlap (or coincide with) an end of each of the first semiconductor layer SCL1, the active layer AL, and the second semiconductor layer SCL2. The side surface of the first bonding electrode BDE1 may form the same plane as the side surface of each of the first semiconductor layer SCL1, the active layer AL, and the second semiconductor layer SCL2.

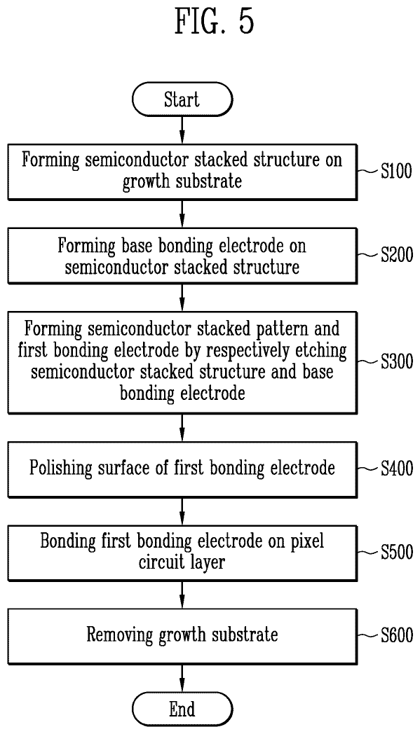

According to the present disclosure, an end of the first bonding electrode BDE1 overlaps (or coincides with) an end of each of the first semiconductor layer SCL1, the active layer AL, and the second semiconductor layer SCL2, such that defects in the light emitting element LD can be reduced and a failure rate of the display device DD can be reduced. This will be described later with reference to drawings after FIG. 5.

FIG. 4 illustrates that the end of the first bonding electrode BDE1 and a portion of the end of the second bonding electrode BDE2 may not coincide with (i.e., may not overlap with) each other when viewed in a plan view, and the end of the first bonding electrode BDE1 and the remaining portion of the end of the second bonding electrode BDE2 may coincide with (i.e., may overlap with) each other. For example, a portion of the end of the second bonding electrode BDE2 may protrude outwardly (e.g., in an extending direction of the first direction DR1 and the second direction DR2) from the end of the first bonding electrode BDE1. However, embodiments of the present disclosure are not limited thereto. According to an embodiment, the end of the first bonding electrode BDE1 and the end of the second bonding electrode BDE2 may coincide with each other in a plan view.

Although not illustrated in FIG. 4, according to an embodiment, the light emitting element LD may further include an insulating film surrounding an outer surface of the light emitting element LD (e.g., the first semiconductor layer SCL1, the active layer AL, and the second semiconductor layer SCL2). The insulating film may include at least one selected from the group consisting of silicon oxide (SiOx), silicon nitride (SiNx), silicon oxynitride (SiOxNy), aluminum oxide (AlxOy), and titanium oxide (TiOx). However, the present disclosure is not limited to the examples described herein.

The insulating layer IL may be disposed on the pixel circuit layer PCL. The insulating layer IL may cover a side surface of the light emitting element. The insulating layer IL may fill a space between light emitting elements LD.

In an embodiment, the insulating layer IL may include an organic material. For example, the insulating layer IL may include one or more selected from the group consisting of acrylic resin, epoxy resin, phenol resin, polyamide resin, and polyimide resin. However, embodiments of the present disclosure are not limited thereto.

The encapsulation layer TFE may be disposed on the light emitting element LD. The encapsulation layer TFE can prevent external air and moisture from penetrating into layers (e.g., a layer on which the light emitting element LD is disposed and the pixel circuit layer PCL) disposed under the encapsulation layer TFE.

The encapsulation layer TFE may be in a form of an encapsulation substrate or an encapsulation film consisting of a single layer. However, embodiments of the present disclosure are not limited thereto, and the encapsulating layer TFE may have a multilayer structure.

When the encapsulating layer TFE is in the form of the encapsulating film of a single layer, the encapsulating layer TFE may include an inorganic layer. According to an embodiment, when the encapsulating layer TFE is formed as a single layer, the encapsulating layer TFE may be formed of a single material. In an example in which the encapsulating layer TFE is in the form of encapsulating film of a multilayer, the encapsulating layer may include an organic layer and an inorganic layer. For example, the encapsulation layer TFE of a multilayer may be in the form of an inorganic layer, an organic layer, and an inorganic layer stacked in sequence.

The upper layer UPL may be disposed on the encapsulating layer TFE. In the embodiment, the upper layer UPL may further include a color filter or the like as a layer for increasing the color purity of the light emitting element LD, but embodiments of the present disclosure are not limited thereto.

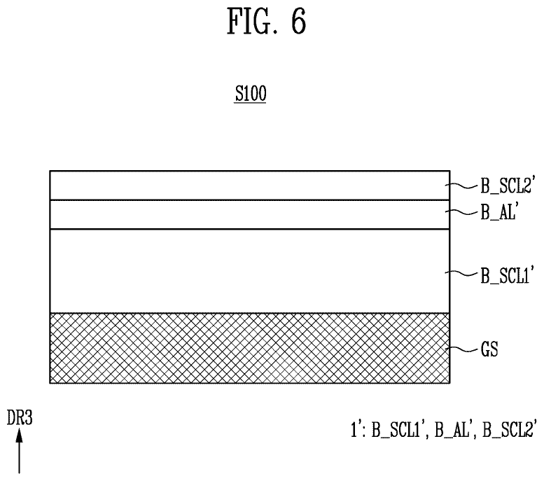

Hereinafter, a method of manufacturing a display device DD will be described with reference to FIGS. 5 to 12. FIG. 5 is a schematic flowchart illustrating a method of manufacturing a display device according to an embodiment. FIGS. 6 to 12 are schematic cross-sectional views illustrating process steps of a method of manufacturing a display device.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 5, a method of manufacturing a display device DD may include forming a semiconductor stacked structure on a growth substrate (S100), forming a base bonding electrode on the semiconductor stacked structure (S200), forming a semiconductor stacked pattern and a first bonding electrode by respectively etching the semiconductor stacked structure and the base bonding electrode (S300), polishing a surface of the first bonding electrode (S400), bonding the first bonding electrode on a pixel circuit layer (S500), and removing the growth substrate (S600).

Referring to FIG. 6, the forming the semiconductor stacked structure on the growth substrate (S100) may include forming a semiconductor stacked structure 1′ on the growth substrate GS. The semiconductor stack structure 1′ may include a first base semiconductor part B_SCL1′, a base active layer part B_AL′, and a second base semiconductor part B_SCL2′. The method may include sequentially forming the first base semiconductor part B_SCL1′, the base active layer part B_AL′, and the second base semiconductor part B_SCL2′ on the growth substrate GS.

The growth substrate GS may be a base plate for growing a target material. For example, the growth substrate GS may be a wafer supportive of epitaxial growth of a material. The growth substrate GS may be a substrate including at least one of GaAs, GaP, GaN, silicon (Si), SiC or InP, but the material for forming the growth substrate GS is not limited to a specific example.

In FIG. 6, the left end and the right end of the growth substrate GS may correspond to an edge area of the growth substrate GS. For example, the left and right ends of the growth substrate GS may overlap the edge area of the growth substrate GS.

Although not illustrated in FIG. 6, according to an embodiment, an undoped semiconductor layer may be further included between the growth substrate GS and the first base semiconductor part B_SCL1′. The undoped semiconductor layer may reduce defects in semiconductor layers formed on the growth substrate GS. According to an embodiment, the undoped semiconductor layer may include GaN that does not include a separate dopant, but the material for forming the undoped semiconductor layer is not limited to a specific example. The first base semiconductor part B_SCL1′ may be epitaxially grown on the growth substrate GS. The first base semiconductor part B_SCL1′ may be a layer for forming the first semiconductor layer SCL1 and may include the same material as the first semiconductor layer SCL1.

The base active layer part B_AL′ may be epitaxially grown on the first base semiconductor part B_SCL1′. The base active layer part B_AL′ may be a layer for forming the active layer AL and may include the same material as the active layer AL.

The second base semiconductor part B_SCL2′ may be epitaxially grown on the base active layer part B_AL′. The second base semiconductor part B_SCL2′ may be a layer for forming the second semiconductor layer SCL2 and may include the same material as the second semiconductor layer SCL2.

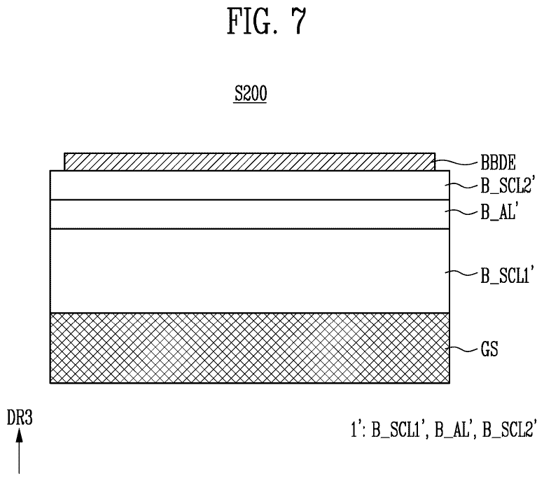

Referring to FIG. 7, in the forming the base bonding electrode on the semiconductor stacked structure (S200), the method may include forming a base bonding electrode BBDE on the semiconductor stacked structure 1′. The base bonding electrode BBDE may be formed on the second base semiconductor part B_SCL2′. The base bonding electrode BBDE may be deposited on the semiconductor stack structure 1′ (or the second base semiconductor part B_SCL2′).

The deposition process may include an atomic layer deposition (ALD) process, a chemical vapor deposition (CVD) process, or the like, but embodiments of the present disclosure are not limited thereto.

In the step (S200) of forming the base bonding electrode on the semiconductor stacked structure, an end of the base bonding electrode BBDE may be mismatched (or non-overlapping) with an end of the semiconductor stacked structure 1′ in one area in a plan view. For example, due to the characteristics of the process equipment for forming the base bonding electrode BBDE, the base bonding electrode BBDE may not be formed (or not deposited) in some areas on the semiconductor stack structure 1′. An end of the base bonding electrode BBDE may not coincide with (may not overlap with) an end of each of the first base semiconductor part B_SCL1′, the base active layer part B_AL′, and the second base semiconductor part B_SCL2′. For example, the end of the base bonding electrode BBDE may not coincide with (may not overlap with) the end of each of the first base semiconductor part B_SCL1′, the base active layer part B_AL′, and the second base semiconductor part B_SCL2′ in a plan view.

The area on the semiconductor stacked structure 1′ where the base bonding electrode BBDE is not formed (or not deposited) may include an edge (or end) area of the growth substrate GS (or the semiconductor stacked structure 1′). For example, the area on the semiconductor stacked structure 1′ where the base bonding electrode BBDE is not formed (or not deposited) may overlap an edge (or end) area of the growth substrate GS (or the semiconductor stacked structure 1′) in a plan view.

If the bonding process is performed in a state where the end of the base bonding electrode BBDE and the end of the semiconductor stacked structure 1′ do not match, the semiconductor stacked structure 1′ may be peeled off in an area where the base bonding electrode BBDE is not formed, and defects in the display device DD may increase.

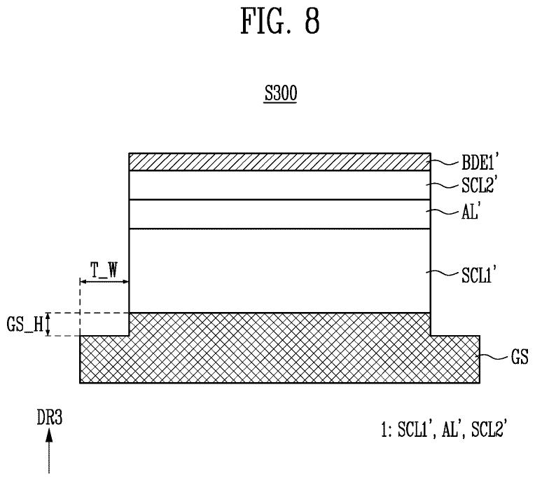

Referring to FIGS. 7 and 8, a method of manufacturing a display device DD according to the present disclosure may include forming the semiconductor stacked pattern and the first bonding electrode by etching the semiconductor stacked structure and the base bonding electrode (S300), and based on the etching, an end of the base bonding electrode BBDE and an end of the semiconductor stacked structure 1′ may coincide with (may overlap) each other. Accordingly, the risk of the semiconductor stacked structure 1′ being peeled off may be reduced, and defects in the display device DD may be reduced.

The method may include forming the semiconductor stacked pattern 1 by etching the semiconductor stack structure 1′. For example, the method may include forming the first semiconductor layer SCL1′, the active layer AL′, and the second semiconductor layer SCL2′ of the semiconductor stacked pattern 1, respectively, by etching the first base semiconductor part B_SCL1′, the base active layer part B_AL′, and the second base semiconductor part B_SCL2′ of the semiconductor stacked structure 1′. The method may include forming the first semiconductor layer SCL1, the active layer AL, and the second semiconductor layer SCL2 of the light emitting element LD illustrated in FIG. 4 by further etching the first semiconductor layer SCL1′, the active layer AL′, and the second semiconductor layer SCL2′ of the semiconductor stacked pattern 1. The method may include forming a first bonding electrode BDE1′ by etching the base bonding electrode BBDE. The method may include forming the first bonding electrode BDE1 shown in FIG. 4 by further etching the first bonding electrode BDE1′.

The process of forming the first bonding electrode BDE1′ and the semiconductor stacked pattern 1 by etching the base bonding electrode BBDE and the semiconductor stacked structure 1′ may correspond to a trimming process. The forming the semiconductor stacked pattern and the first bonding electrode by etching the semiconductor stack structure and the base bonding electrode (S300) may include trimming the base bonding electrode BBDE and the semiconductor stack structure 1′.

For example, the process of etching (or trimming) the base bonding electrode BBDE and the semiconductor stacked structure 1′ may be a process of removing a portion of a periphery (e.g., a side periphery) of the base bonding electrode BBDE and the semiconductor stacked structure 1′. The method of manufacturing the display device DD according to an embodiment of the present disclosure can remove a defect (e.g., a crack) existing at the periphery of the semiconductor stacked structure 1′ by trimming the periphery of the base bonding electrode BBDE and the semiconductor stacked structure 1′, and can reduce the risk of a defect existing at the periphery of the semiconductor stacked structure 1′ being formed to the center of the display device DD.

The forming of the semiconductor stacked pattern and the first bonding electrode by etching the semiconductor stack structure and the base bonding electrode (S300) may be performed after the forming the base bonding electrode on the semiconductor stack structure (S200), and thus the bonding strength between the semiconductor stack structure 1′ and the base bonding electrode BBDE may be improved. In an example in which the etching process (e.g., the trimming process) for the semiconductor stacked structure 1′ is performed and the base bonding electrode BBDE is formed, particles generated during the etching process for the semiconductor stacked structure 1′ may act as foreign substances between the semiconductor stacked structure 1′ and the base bonding electrode BBDE. Therefore, the bonding strength of the base bonding electrode BBDE can be reduced.

The method of manufacturing the display device DD according to the present disclosure may include refraining from further etching (or trimming) the semiconductor stacked structure 1′ between a process of forming the semiconductor stacked structure 1′ and a process of forming the base bonding electrode BBDE, such that a bonding strength between the semiconductor stacked structure 1′ and the base bonding electrode BBDE is improved, and an electrical connection reliability of the display device DD is increased.

In the forming the semiconductor stacked pattern and the first bonding electrode by etching the semiconductor stack structure and the base bonding electrode (S300), the method may include simultaneously etching the semiconductor stack structure 1′ and the base bonding electrode BBDE. For example, the method may include etching the semiconductor stack structure 1′ and the base bonding electrode BBDE within the same etching process. For example, the semiconductor stack structure 1′ and the base bonding electrode BBDE may be etched integrally.

The method may include etching the semiconductor stack structure 1′ and the base bonding electrode BBDE such that ends of the semiconductor stack structure 1′ and the base bonding electrode BBDE coincide with each other. For example, the end of the semiconductor stacked pattern 1 and the end of the first bonding electrode BDE1′ may coincide with each other. The end of the semiconductor stacked pattern 1 and the end of the first bonding electrode BDE1′ may overlap each other in a plan view. The side surface of the semiconductor stacked pattern 1 and the side surface of the first bonding electrode BDE1′ may form the same plane. For example, the side surface of the semiconductor stacked pattern 1 and the side surface of the first bonding electrode BDE1′ may be arranged on the same plane (e.g., a plane extending in the third direction DR3).

The method may include etching each of the two side surfaces of the semiconductor stack structure 1′ according to a predetermined thickness T_W. The thickness T_W at which the semiconductor stack structure 1′ is etched may be defined as the direction in which the plane on which the growth substrate GS is disposed extends (e.g., the first direction DR1 or the second direction DR2). The thickness T_W may be 2 mm or less. In an example in which the thickness T_W exceeds 2 mm, the semiconductor stacked structure 1′ may be excessively etched, which can reduce process efficiency. The thickness according to which the base bonding electrode BBDE is etched may be smaller than the thickness T_W, and the base bonding electrode BBDE may be etched such that ends of the semiconductor stacked pattern 1 are aligned.

The step of etching (or trimming) the semiconductor stacked structure 1′ and the base bonding electrode BBDE may further include the step of etching (or trimming) the semiconductor stacked structure 1′ and the base bonding electrode BBDE using at least one of a knife or a laser. For example, the method may include etching (or trimming) the side surface of the semiconductor stack structure 1′ and the side surface of the base bonding electrode BBDE using at least one of a knife or a laser while rotating the growth substrate GS.

In the embodiment, in the forming the semiconductor stacked pattern and the first bonding electrode (S300) by etching the semiconductor stack structure and the base bonding electrode, at least a portion of the growth substrate GS may be further etched. The growth substrate GS may be etched within the process of etching the semiconductor stack structure 1′ and the base bonding electrode BBDE. In an example in which a process of etching the semiconductor stack structure 1′ and the base bonding electrode BBDE is performed, at least a portion of the upper surface of the growth substrate GS may be further etched in the thickness direction of the growth substrate GS (e.g., in the opposite direction to the third direction DR3). At least a portion of the side surface of the growth substrate GS may form the same plane as the side surface of the semiconductor stack structure 1′. The method may include further etching at least a portion of the growth substrate GS such that a step GS_H is formed in the upper surface of the growth substrate GS.

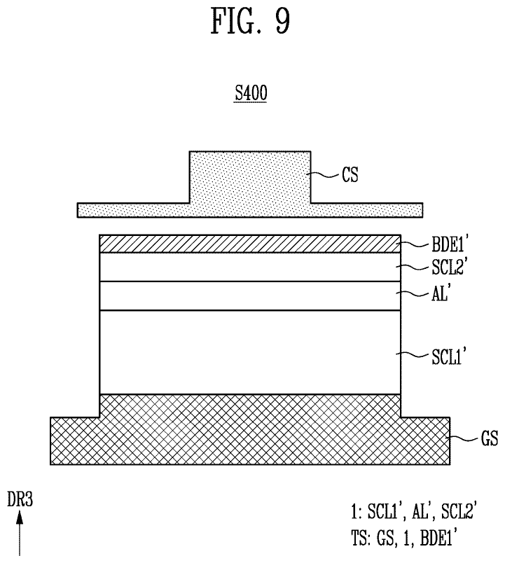

Referring to FIG. 9, the polishing a surface of the first bonding electrode (S400), may include polishing the upper surface of the first bonding electrode BDE1′. The upper surface of the first bonding electrode BDE1′ may be a surface opposite to the surface facing the second semiconductor layer SCL2.

In the polishing a surface of the first bonding electrode (S400), the method may include performing a polishing process (e.g., chemical mechanical polishing (CMP)) which polishes the upper surface of the first bonding electrode BDE1′ using a polishing apparatus CS. The method may include polishing at least a portion of the upper surface of the first bonding electrode BDE1′ such that the portion of the upper surface is a flat surface.

The method of manufacturing the display device DD according to the present disclosure may include the polishing a surface of the first bonding electrode (S400), thereby removing particles generated in the trimming process, such that the first bonding electrode BDE1′ may be more firmly bonded (e.g., to other elements or layers).

After the first bonding electrode BDE1′ is polished, the method may include forming a transfer structure TS. The transfer structure TS may include a growth substrate GS, a semiconductor stacked pattern 1, and a first bonding electrode BDE1′. The method may include transferring the transfer structure TS onto the pixel circuit layer PCL to form the light emitting element LD.

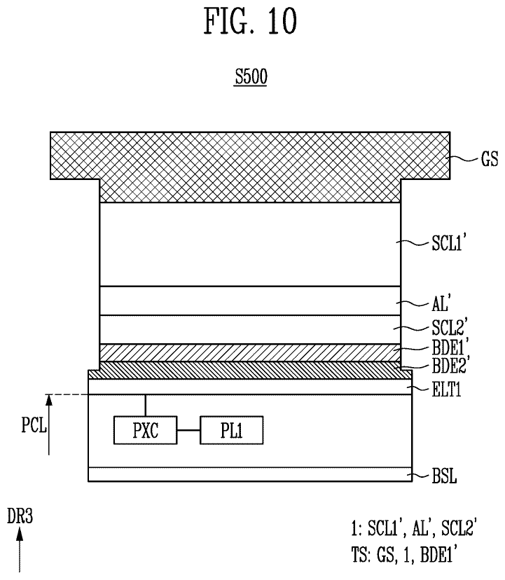

Referring to FIG. 10, the method of manufacturing the display device DD may include forming a first electrode ELT1 and a second bonding electrode BDE2′ on the pixel circuit layer PCL. The method may include, before the bonding the first bonding electrode on the pixel circuit layer (S500), forming the first electrode ELT1 and the second bonding electrode BDE2′ on the pixel circuit layer PCL. The first electrode ELT1 may be formed on the pixel circuit layer PCL. The second bonding electrode BDE2′ may be formed on the first electrode ELT1. The second bonding electrode BDE2′ may form the second bonding electrode BDE2 illustrated in FIG. 4. In an embodiment, the second bonding electrode BDE2′ may be formed such that the second bonding electrode BDE2′ has a larger area than the first bonding electrode BDE1′ in a plan view.

In the bonding the first bonding electrode on the pixel circuit layer (S500), the method may include bonding the first bonding electrode BDE1′ on the pixel circuit layer PCL. The transfer structure TS may be flipped and disposed such that the upper surface of the first bonding electrode BDE1′ faces the pixel circuit layer PCL. For example, the upper surface of the polished first bonding electrode BDE1′ may face the upper surface of the pixel circuit layer PCL.

The first bonding electrode BDE1′ and the second bonding electrode BDE2′ may be bonded to each other by a specific bonding method and may be electrically connected. The bonding method may include an anisotropic conductive film (ACF) bonding method, a laser assist bonding (LAB) method using laser, an ultrasonic bonding method, a bump-ball surface mount method (e.g., ball grid array (BGA)), a thermo compression bonding (TC) method, or the like. The thermo compression bonding method may refer to a method of electrically and physically connecting the first bonding electrode BDE1′ and the second bonding electrode BDE2′ by contacting the first bonding electrode BDE1′ and the second bonding electrode BDE2′, heating the first bonding electrode BDE1′ and the second bonding electrode BDE2′ to a temperature higher than a melting point of the first bonding electrode BDE1′ and the second bonding electrode BDE2′, and then applying pressure to the first bonding electrode BDE1′ and the second bonding electrode BDE2′.

According to the method of manufacturing the display device DD according to the present disclosure, the forming the semiconductor stacked pattern and the first bonding electrode by etching the semiconductor stacked structure and the base bonding electrode (S300) may be performed before bonding the first bonding electrode on the pixel circuit layer (S500), and when forming a metal layer on the pixel circuit layer PCL, the resistance of the metal layer may be reduced. In an example in which a trimming process for the transfer structure TS is performed after the bonding the first bonding electrode on the pixel circuit layer (S500), at least a portion of the pixel circuit layer PCL may be etched together (e.g., an upper surface of the pixel circuit layer PCL may be etched together), such that a step of the pixel circuit layer PCL may be excessively formed. In this case, the resistance of the metal layer may increase when the metal layer is formed.

The method of manufacturing the display device DD according to the present disclosure may reduce the risk of damage to the growth substrate GS and the semiconductor stack structure 1′ by performing a trimming process on the transfer structure TS before the bonding the first bonding electrode on the pixel circuit layer (S500).

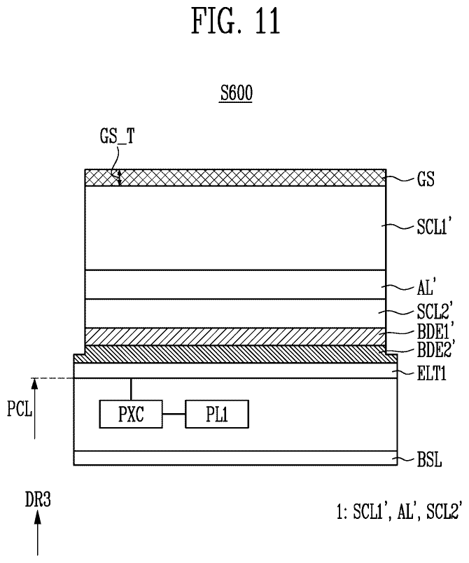

Referring to FIG. 11, the removing the growth substrate (S600) may include grinding a portion of the growth substrate GS. A portion of the growth substrate GS may be ground. The growth substrate GS may be ground to have a growth substrate thickness GS_T. The method may include grinding the growth substrate GS until the growth substrate GS has a growth substrate thickness GS_T. The growth substrate thickness GS_T may be defined in the third direction DR3. The thickness of the growth substrate thickness GS_T may be 30μm to 70 μm. In an embodiment, the thickness of the growth substrate thickness GS_T may be 50 μm.

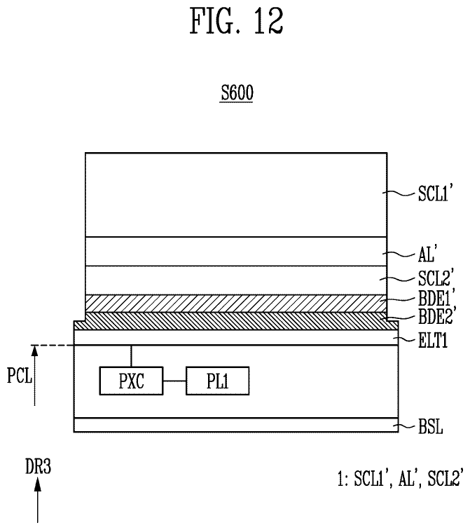

Referring to FIG. 12, the removing the growth substrate (S600) may include etching the remaining portion of the growth substrate GS. The method may include etching the remaining portion of the growth substrate GS remaining after grinding. The etching of the growth substrate GS may remove the growth substrate GS and expose the upper surface of the first semiconductor layer SCL1. The method of manufacturing the display device DD according to the present disclosure may reduce process costs by removing a portion of a growth substrate GS through a grinding process and then removing the remaining portion of the growth substrate GS through an etching process.

In connection with FIG. 4, in the embodiment, after the removing the growth substrate (S600), the method may include etching a portion of the semiconductor stacked pattern 1, thereby forming a plurality of light emitting elements LD. For example, after the removing the growth substrate (S600), the method may include forming the first semiconductor layer SCL1, the active layer AL, and the second semiconductor layer SCL2 of the light emitting elements LD by dry etching a portion of the semiconductor stacked pattern 1. However, embodiments of the present disclosure are not limited thereto. For example, the method may include further etching a portion of the semiconductor stacked pattern 1 before the removing the growth substrate (S600).

For the dry etching process, a dry etching method such as, for example, a reactive ion etching (IE) method, a reactive ion beam etching (RIBE) method, or an inductively coupled plasma reactive ion etching (ICP-RIE) method may be used. However, the etching method is not necessarily limited to a specific example.

Although not illustrated in FIG. 12, the method may further include forming an insulating film which covers the side surface of the semiconductor stacked pattern 1. The insulating film may expose the first and second bonding electrodes BDE1′ and BDE2′. After the light emitting element LD is formed, the method may include further forming the insulating layer IL, the second electrode ELT2, the encapsulating layer TFE, and the upper layer UPL, and the display device DD may be manufactured.

A display device according to an embodiment is applicable to various types of electronic devices. In an embodiment, an electronic device includes the above-described display device and may further include other modules or devices having additional functions in addition to the display device.

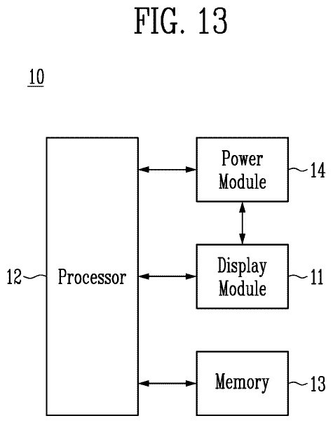

FIG. 13 is a block diagram of an electronic device according to an embodiment. Referring to FIG. 13, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

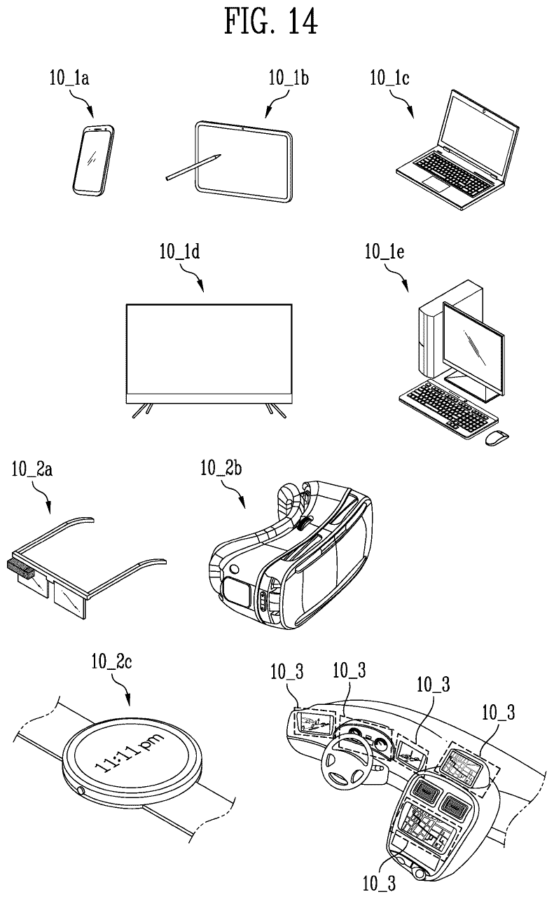

FIG. 14 shows schematic views of various embodiments of an electronic device.

Referring to FIG. 14, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

As described herein, while the present disclosure has been illustrated and described with reference to certain embodiments thereof, it will be understood by those skilled in the art that various changes in forms and details may be made therein without departing from the spirit and scope of the present disclosure as defined by the appended claims and their equivalents.

Accordingly, the technical scope of the present disclosure may be determined by on the technical scope of the accompanying claims.

What is claimed is:

1. A method of manufacturing a display device, comprising:
forming a semiconductor stacked structure on a growth substrate;
forming a base bonding electrode on the semiconductor stacked structure;
forming a semiconductor stacked pattern and a first bonding electrode by respectively etching the semiconductor stacked structure and the base bonding electrode; and
bonding the first bonding electrode on a pixel circuit layer.

2. The method of claim 1, wherein the forming the semiconductor stacked pattern and the first bonding electrode comprises trimming a side surface of each of the semiconductor stacked structure and the base bonding electrode.

3. The method of claim 2, wherein the trimming is performed between the forming the base bonding electrode on the semiconductor stacked structure and the bonding the first bonding electrode on the pixel circuit layer.

4. The method of claim 2, wherein the trimming comprises etching the semiconductor stacked structure with at least one of a knife and a laser while rotating the growth substrate.

5. The method of claim 1, wherein the forming the semiconductor stacked pattern and the first bonding electrode comprises etching the semiconductor stacked structure and the base bonding electrode such that an end of the semiconductor stacked pattern and an end of the first bonding electrode are coincided.

6. The method of claim 1, wherein the forming the semiconductor stacked pattern and the first bonding electrode comprises etching the semiconductor stacked structure and the base bonding electrode such that a side surface of the semiconductor stacked pattern and a side surface of the first bonding electrode form a same plane.

7. The method of claim 1, wherein the semiconductor stacked pattern and the first bonding electrode are formed within a same etching process.

8. The method of claim 1, wherein:
the semiconductor stacked structure is etched to a thickness of 2 mm or less, and
the thickness is defined in a direction in which a plane on which the growth substrate is disposed extends.

9. The method of claim 1, wherein the forming the semiconductor stacked pattern and the first bonding electrode comprises etching the growth substrate such that a step is formed in an upper surface of the growth substrate.

10. The method of claim 1, further comprising polishing a surface of the first bonding electrode.

11. The method of claim 1, further comprising forming a second bonding electrode on the pixel circuit layer,
wherein in the bonding the first bonding electrode, the first bonding electrode is bonded to the second bonding electrode.

12. The method of claim 1, wherein an end of the base bonding electrode formed in the forming the base bonding electrode does not coincide with an end of the semiconductor stacked structure.

13. The method of claim 1, wherein:
in the forming the base bonding electrode, the base bonding electrode is not deposited on an area of the semiconductor stacked structure, and
the area overlaps an edge of the semiconductor stacked structure in a plan view.

14. The method of claim 1, further comprising removing the growth substrate, wherein the removing the growth substrate comprises:
grinding a portion of the growth substrate; and
etching a remaining portion of the growth substrate.

15. The method of claim 14, wherein the grinding a portion of the growth substrate comprises grinding the growth substrate until a growth substrate thickness of the growth substrate is 30 μm to 70 μm.

16. The method of claim 1, wherein:
the growth substrate comprises silicon, and
the semiconductor stacked structure comprises:
a first base semiconductor part epitaxially grown on the growth substrate,
a base active layer part epitaxially grown on the first base semiconductor part, and
a second base semiconductor part epitaxially grown on the base active layer part.

17. A display device comprising:
a pixel circuit layer;
a first bonding electrode disposed on the pixel circuit layer; and
a light emitting element disposed on the first bonding electrode,
wherein the light emitting element comprises:
a first semiconductor layer;
a second semiconductor layer; and
an active layer interposed between the first semiconductor layer and the second semiconductor layer,
wherein each of the first semiconductor layer, the second semiconductor layer, and the active layer has an end that coincides with an end of the first bonding electrode.

18. The display device of claim 17, wherein a side surface of the first semiconductor layer, a side surface of the second semiconductor layer, and a side surface of the active layer each forms a same plane as a side surface of the first bonding electrode.

19. The display device of claim 17, further comprising a second bonding electrode disposed on the pixel circuit layer,
wherein:
the second bonding electrode is bonded to the first bonding electrode, and
a portion of an end of the second bonding electrode coincides with the end of the first bonding electrode.

20. The display device of claim 19, wherein a remaining portion of the end of the second bonding electrode, excluding the portion of the end of the second bonding electrode, protrudes outwardly from the end of the first bonding electrode.

21. An electronic device comprising:
a display device comprising:
a pixel circuit layer;
a first bonding electrode disposed on the pixel circuit layer; and
a light emitting element disposed on the first bonding electrode,
wherein the light emitting element comprises:
a first semiconductor layer;
a second semiconductor layer; and
an active layer interposed between the first semiconductor layer and the second semiconductor layer,
wherein each of the first semiconductor layer, the second semiconductor layer, and the active layer has an end that coincides with an end of the first bonding electrode.
